(19) United States
(12) Patent Application Publication
(10) Pub. No.: US 2009/0001597 A1
(43) Pub. Date: Jan. 1, 2009

(54) SEMICONDUCTOR DEVICE HAVING AN INTERCONNECT ELECTRICALLY CONNECTING A FRONT AND BACKSIDE THEREOF AND A METHOD OF MANUFACTURE THEREFOR

(75) Inventors: Rex W. Pirkle, Denison, TX (US); Eric M. Bernard, Sherman, TX (US); Sean M. Malolepszy, Sherman, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/769,209

(22) Filed: Jun. 27, 2007

(51) Int. Cl. H01L 23/522; H01L 21/4763; H01L 21/768; H01L 23/52

(52) U.S. Cl. 257/777; 257/780; 438/109; 438/618; 257/E21.597; 257/E23.169; 257/E23.141; 257/E21.495

(57) ABSTRACT

The disclosure provides a semiconductor device and method of manufacture. The method for manufacturing the semiconductor device includes providing a substrate having circuitry located thereover. The surface of the substrate is subjected to a first anisotropic etch, the first anisotropic etch forming an opening that extends only partially into the substrate. An opposing surface of the substrate is subjected to a second anisotropic etch, the second anisotropic etch forming an opposing opening that extends only partially into the substrate. Additionally, a first conductive layer is formed in electrical contact with the circuitry and lining sidewalls of the opening. A second conductive layer is formed along at least a portion of the second opposing surface and lining sidewalls of the opposing opening. The first conductive layer and the second conductive layer electrically contact one another.

### TECHNICAL FIELD OF THE INVENTION

The disclosure is directed, in general, to a semiconductor device and, more specifically, to a semiconductor device having an interconnect electrically connecting a front and backside thereof and a method of manufacture therefore.

### BACKGROUND OF THE INVENTION

As it becomes possible to fit more and more circuit elements onto a single substrate, a larger number of interconnects may be needed on the substrate to connect the circuit elements to off-substrate circuitry. Conventional interconnects are typically formed on the same side of the substrate as the circuit elements (the “frontside” of the substrate), and terminate at contact pads formed around the perimeter of the frontside of the substrate. With each increase in the number of circuit elements on a single substrate, the contact pads and interconnects become more crowded around the perimeter of the substrate. This may require reducing the size of the interconnects to squeeze them into the available space. The reduced interconnect size, however, may lead to a high interconnect resistance caused by the small cross-sectional area of the interconnects.

The industry, in turn, has experimented with various different interconnect configurations to address these problems. Unfortunately, these different interconnect configurations are either incapable of appropriately addressing the problem or difficult to integrate into the manufacturing process flow. Accordingly, what is needed in the art is a semiconductor device and method of manufacture therefore that does not experience the above-discussed problems.

### SUMMARY OF THE INVENTION

To address the above-discussed deficiencies of the prior art, the disclosure provides a semiconductor device and method of manufacture therefore. The method for manufacturing the semiconductor device, in one embodiment, includes providing a substrate having active semiconductor circuitry located over a surface thereof. The method further includes subjecting the surface of the substrate to a first anisotropic etch, the first anisotropic etch forming an opening that extends only partially into the substrate. The method additionally includes subjecting an opposing surface of the substrate to a second anisotropic etch, the second anisotropic etch forming an opposing opening that extends only partially into the substrate. moreover, the method includes forming a first conductive layer in electrical contact with at least a portion of the active semiconductor circuitry and lining sidewalls of the opening, and forming a second conductive layer along at least a portion of the second opposing surface and lining sidewalls of the opposing opening. The first conductive layer and the second conductive layer, in this embodiment, electrically contact one another and are configured to provide an electrical connection between the at least a portion of the active semiconductor circuitry and a conductive feature located proximate the second opposing surface.

Additionally provided is the semiconductor device. The semiconductor device, without limitation, may include a substrate having active semiconductor circuitry located over a surface thereof and an interconnect electrically coupling at least a portion of the active semiconductor circuitry and an opposing surface of the substrate. The interconnect, in this embodiment, includes a first portion extending from the surface, the first portion including an opening having a first conductive layer in electrical contact with at least a portion of the active semiconductor circuitry and lining sidewalls of the opening. The interconnect further includes a second portion extending from the opposing surface, the second portion having a second conductive layer along at least a portion of the second opposing surface and lining sidewalls of the opposing opening. The first conductive layer and the second conductive layer electrically contact one another and are configured to provide an electrical connection between the at least a portion of the active semiconductor circuitry and a conductive feature located proximate the second opposing surface. Additionally, the interconnect has a hour glass cross-section.

### BRIEF DESCRIPTION OF THE DRAWINGS

For a more complete understanding of the disclosure, reference is now made to the following descriptions taken in conjunction with the accompanying drawings, in which:

FIGS. 1 thru 13 illustrate detailed steps of one example embodiment for manufacturing a semiconductor device in accordance with this disclosure; and

FIG. 14 illustrates an alternative embodiment of the disclosure.

### DETAILED DESCRIPTION

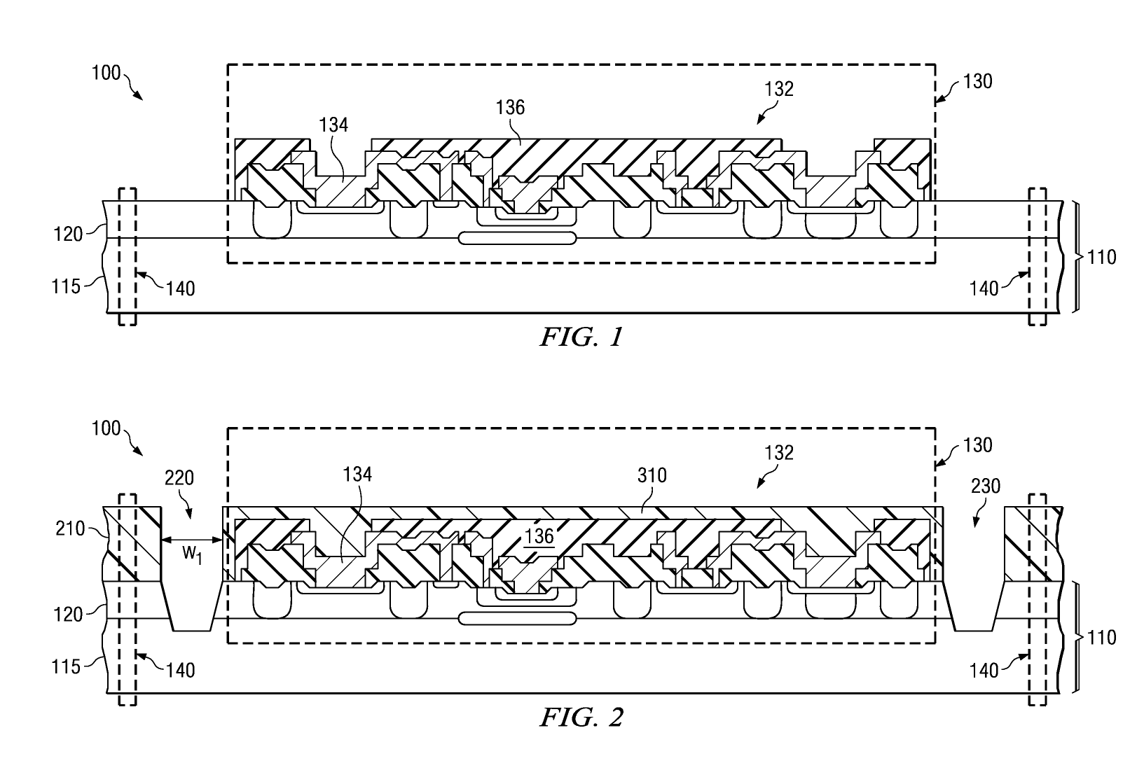

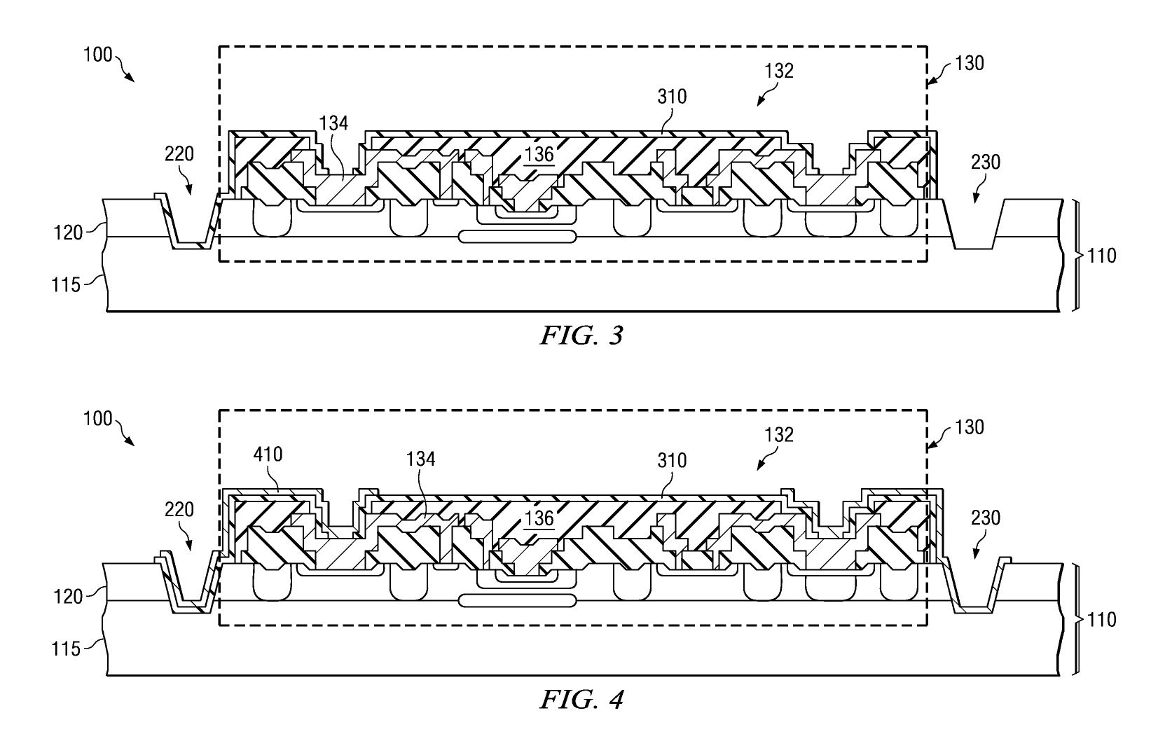

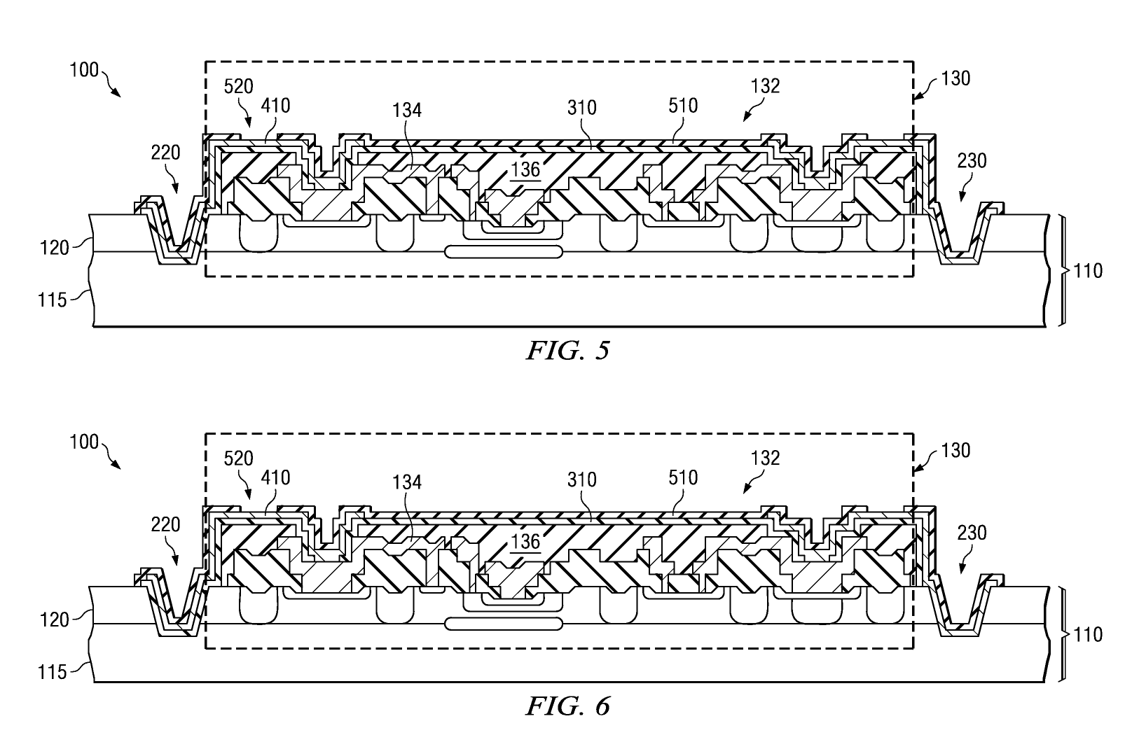

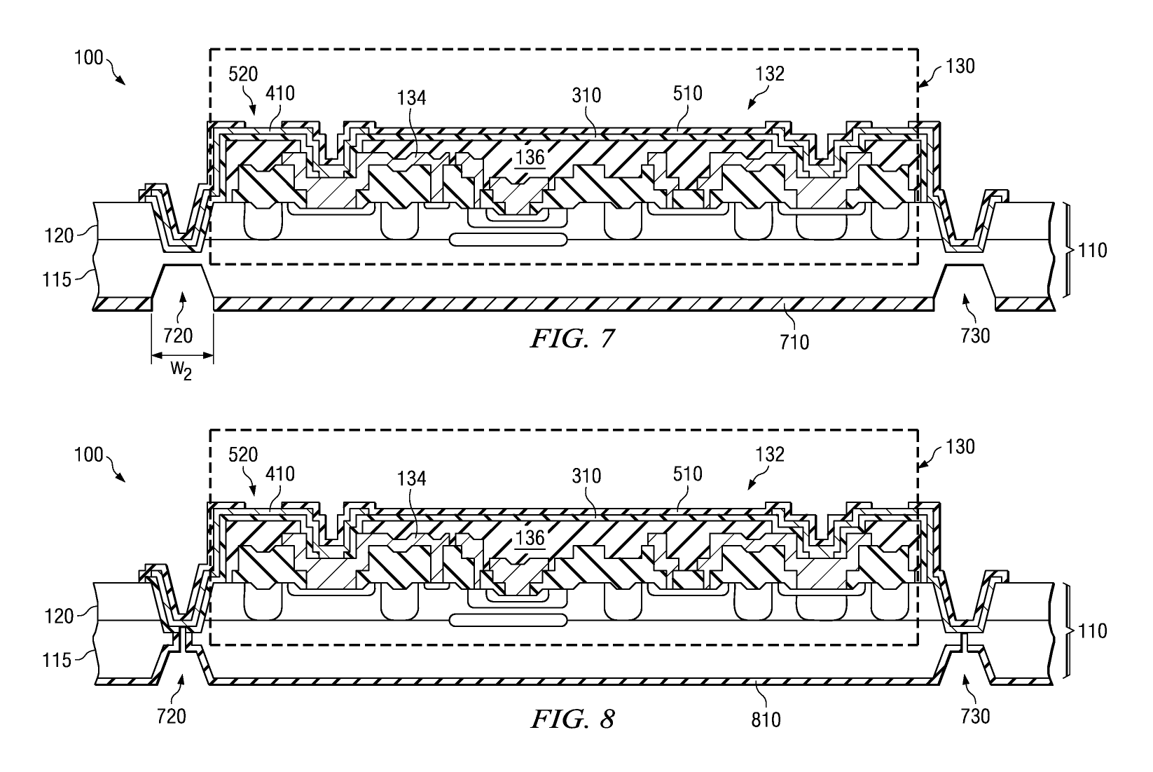

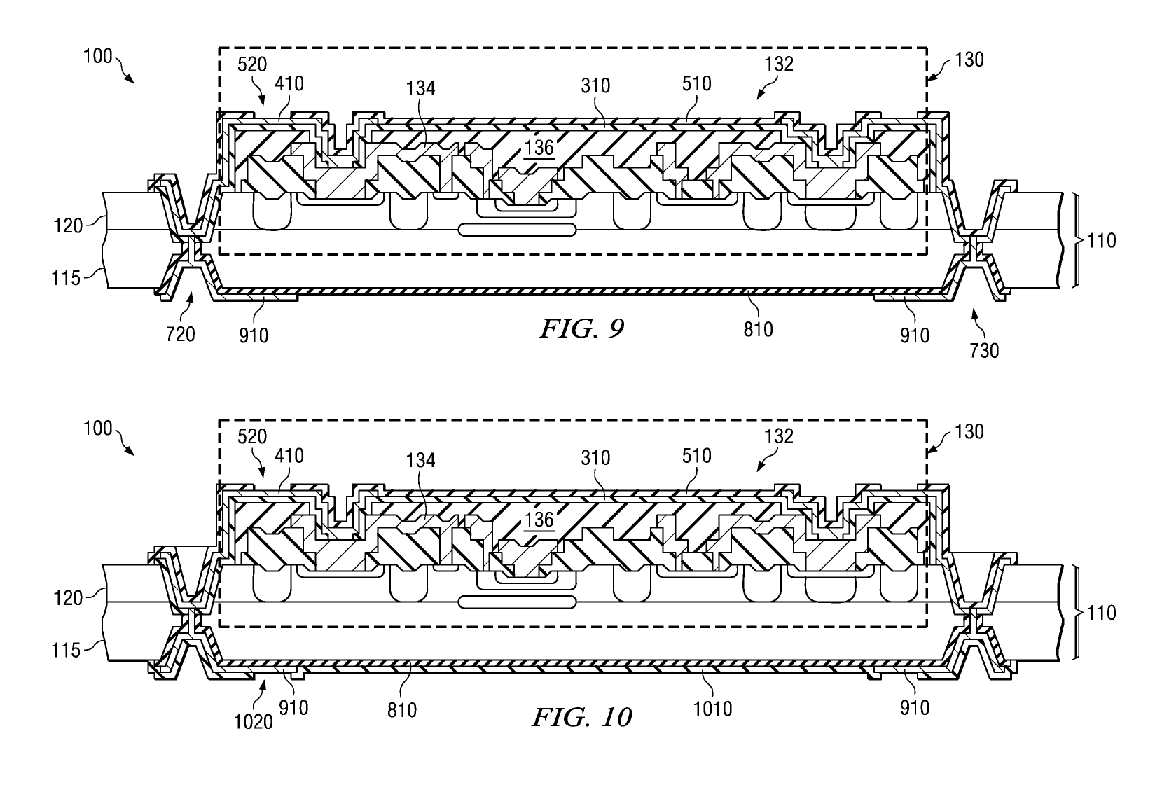

FIGS. 1 thru 13 illustrate detailed steps of one example embodiment for manufacturing a semiconductor device in accordance with this disclosure. FIG. 1 illustrates a semiconductor device 100 at an initial stage of manufacture. The device 100 includes a substrate 110. The substrate 110 may comprise one or more layers and remain within the purview of the disclosure. In the embodiment of FIG. 1, however, the substrate 110 comprises a wafer substrate 115 and an epitaxial silicon layer 120. Other configurations might also exist. For instance, the substrate 110 might, in a different embodiment, comprise a silicon-on-insulator substrate.

Located above a surface of the substrate 110 is active semiconductor circuitry 130. The active semiconductor circuitry 130 of FIG. 1 is configured as a junction isolated bipolar transistor device. For instance, the active semiconductor circuitry 130 includes a bipolar transistor 132, one or more bond pads 134 for electrically contacting the bipolar transistor 132, and a passivation layer 136 located over the bipolar transistor 132. The passivation layer 136, in the embodiment shown, exposes at least a portion of the one or more bond pads 134.

The active semiconductor circuitry 130, in accordance with the disclosure, may comprise many other types of semiconductor components, conventional and not. Accordingly, the active semiconductor circuitry 130 illustrated is FIG. 1 is merely an example of the types of semiconductor components that might be included within the active semiconductor circuitry 130. Manufacturing processes, conventional and not, may be used to manufacture the active semiconductor circuitry 130.

Located on either side of the active semiconductor circuitry 130 are scribe line areas 140. The scribe line areas 140 are areas of the device 100 that define the boundaries of different semiconductor chips. Ultimately, these scribe line areas 140 will generally be subjected to a wafer dicing process, resulting in individual semiconductor dies.

FIG. 2 illustrates the device 100 of FIG. 1 after patterning a resist layer 210, and using the patterned resist layer 210 to form a first opening 220 and second opening 230 in the substrate 110. Those skilled in the art understand the process of forming the patterned resist layer 210. The process would generally begin by depositing a conformal layer of radiation sensitive resist coating (e.g., a conformal layer of resist) over the substrate 110. The radiation sensitive resist coating would then be patterned by selectively exposing the resist through a mask. In turn, the exposed areas of the coating become either more or less soluble than the unexposed areas, depending on the type of resist. A solvent developer would then be used to remove the less soluble areas leaving the patterned resist layer 210.

The patterned resist layer 210, and in certain instances a patterned hardmask layer located therebelow (not shown), may then be used to form the first opening 220 and second opening 230. The first opening and second opening 220, 230, in accordance with this disclosure, may be formed by subjecting the exposed portion of the substrate 110 to an appropriate etch. In one embodiment, the appropriate etch is an anisotropic etch. The anisotropic etch, in an example embodiment, may form V-shaped openings by means of an etchant that attacks the (100) crystal plane about 30 times faster than the (111) plane. A suitable etchant, in this example embodiment, is about 65% hydrazine, about 35% water at about 100° C. However, other suitable etchants may also exist. Additional information regarding this etch and other suitable etches may be found in the publication entitled Integrated Circuit Engineering, Design Fabrication and Applications”, by Arthur B. Glaser, which is incorporate herein by reference.

The first and second openings 220, 230, may be formed to any desired depth. Variations in this depth can be employed for different purposes. For instance, in certain example embodiments the first and second openings 220, 230 will have a shallower depth than the third and fourth opposing openings 720, 730 (FIG. 7). This configuration may help reduce the circuit area of the top side of the device 100. Nevertheless, in this example embodiment, the width (w₂) of the patterned resist layer 710 should generally be increased to compensate for the increased depth of the third and fourth opposing openings 720, 730. As is illustrated, the first and second openings 220, 230 are located within the boundaries defined by the scribe line areas 140.

The appropriate width (w₁) of the openings in the patterned photoresist layer 210 is a function of the substrate 110 thickness (e.g., wafer substrate 115 and epitaxial layer 120 thickness in one embodiment), desired depth of the openings 220, 230, and the particular etchant used. For example, the above discussed etchant provides the first opening 220 and the second opening 230 with a sidewall angle of about 54 degrees relative to the surface. Knowing this, as well as the desired depth of the first and second openings 220, 230, the appropriate width (w₁) may be calculated.

The particular shape of the opening in the patterned photoresist 210, and thus the openings 220, 230 in the substrate 110 may also vary. For example, the opening in the patterned photoresist 210 may take the shape of a square, rectangle or circle, among others. If a square opening is used, such a process would remove substrate material in the shape of an inverted pyramid, with the opening being the base of the pyramid. In this example, an uninterrupted etch would be self-stopping at the pyramid vertex, thereby allowing a controlled depth. However, it is generally desirable to terminate the etch prior to the vertex formation, resulting in a truncated pyramid opening, and leaving a square surface in a bottom of it. Again, it should be noted that the openings 220, 230 may also be formed in a V-groove profile, among others, by changing the etched openings to a rectangular shape.

FIG. 3 illustrates the device 100 of FIG. 2 after forming a first insulative layer 310 along sidewalls of the opening 220. The first insulative layer 310, in this embodiment, also extends over an upper surface of the passivation layer 136, and exposes the one or more bond pads 134 for subsequent electrical connections thereto. In the example embodiment of FIG. 3, the first insulative layer 310 does not remain along sidewalls of the opening 230. As will be further evident below, the exclusion of the first insulative layer 310 from the sidewalls of the opening 230 allows the interconnect formed from the opening 230 to form a ground contact.

The first insulative layer 310 may comprise a host of different materials. In the example embodiment of FIG. 3, the first insulative layer 310 comprises an oxide. The first insulative layer 310 could also comprise a nitride or a combination of an oxide and nitride, among others. The first insulative layer 310 may also be formed using a host of different processes. In the example embodiment of FIG. 3 the first insulative layer 310 is deposited on an entire surface of the device 100 to a thickness ranging from about 800 nm to about 1400 nm (e.g., about 1100 nm in one embodiment) using a chemical vapor deposition (CVD) process. The conformal layer could then be selectively patterned, for example removing the first insulative layer 310 from the scribe separation areas and the second opening 230, among other areas. The first insulative layer 310 would remain over the other regions of the device 100.

FIG. 4 illustrates the device 100 of FIG. 3 after forming a first conductive layer 410 in electrical contact with at least a portion of the active semiconductor circuitry 130 and lining sidewalls of the first opening 220. The first conductive layer 410, in this example embodiment, is in electrical contact with the one or more bond pads 134 exposed by the first insulative layer 310. The first conductive layer 410 also lines the sidewalls of the second opening 230. The existence of the first insulative layer 310 in the first opening 220 causes the first conductive layer 410 in the first opening 220 to be isolated from the substrate 110. To the contrary, the lack of existence of the first insulative layer 310 in the second opening 230 causes at least a portion of the first conductive layer 410 in the second opening 230 to be in contact with the substrate 110 (e.g., the epitaxial layer 120).

The first conductive layer 410 may comprise many different materials. For example, the first conductive layer 410 may comprise many different metals or alloys and remain within the purview of the disclosure. In certain embodiments, the first conductive layer 410 comprises a conductive material that may be electroplated or sputter deposited. For instance, the first conductive layer 410 might comprise aluminum, copper, or other suitable combinations of metals commonly used in the manufacture of semiconductor devices. Other materials might also be used.

The first conductive layer 410 may be formed using any suitable manufacturing process. Because of the relative small size and high aspect ratio of the openings 220, 230, a sputtering or electro-deposition process would work well. For example, the embodiment of FIG. 4 uses a sputter deposition process to deposit a conformal layer of the first conductive layer 410 over the entire device 100. The conformal layer of the first conductive layer 410 may then be selectively etched, for example removing the first conductive layer 410 from the scribe line areas 140, thus resulting in the first conductive layer 410 illustrated in FIG. 4. Top side metal areas that are normally formed in conventional designs, such as bond pad openings, probe test points, fuses, and the such, may be patterned and etched in this process step. The first conductive layer 410 may be formed to any suitable thickness.

FIG. 5 illustrates the device 100 of FIG. 4 after forming a topside passivation layer 510 over the first conductive layer 410. In the process of FIG. 5, the topside passivation layer 510 is deposited over the top surface of the device 100. Thereafter, openings are formed within the topside passivation layer 510, as might be the case in conventional processes. Accordingly, the topside passivation layer 510 insulates all of the topside of the device 100 but a region configured as a topside contact pad 520. A variety of materials and processes, convention and not, may be used to form and pattern the topside passivation layer 510.

In an alternative embodiment, the step of patterning the topside passivation layer 510 may be delayed and performed just prior to test and die separation. This would provide an effective barrier against contamination from subsequent processing. In yet another embodiment, it is possible and (may be very desirable) to entirely seal the topside surface with topside passivation layer 510. In this embodiment the topside passivation layer 510 would only be removed from the scribe line areas 140. In such cases, the external electrical connections would be made from the backside routings through the substrate 110, and probing would be done on an inverted wafer.

FIG. 6 illustrates the device 100 of FIG. 5 after grinding an opposing surface of the substrate 110. In this step, the substrate 110 is background, polished and cleaned to an appropriate thickness. Since the backside third and fourth openings 720, 730 must be sufficiently large to intersect the first and second openings 220, 230, thinning the substrate 110 reduces the printed dimensions of the third and fourth openings 720, 730. The backgrind also helps remove impurities and crystal imperfections that may form as a result of wafer gettering processes. Additionally, if sufficiently thinned, backside printing steps may require fewer adjustments of photolithography equipment (or fewer mask steps) if printed depths remain within specifications of the equipment depth of field. Since in this process patterning may occur in planes of significantly differing height, this is an important consideration. Those skilled in the art understand the steps required to backgrind the substrate 110.

Before proceeding with the formation of the third and fourth openings 720, 730 in the opposing surface of the substrate 110, a mask alignment procedure should be used to align top side patterns with initial backside patterns. It is suggested that immediately following backgrind, metal alignment patterns may be formed in known locations on the backside of the device 100. The location of these alignment patterns may be measured and compared against similar patterns already printed on the topside. This may be done by fixing the wafer and making direct x,y measurements from calibrated top and bottom reference points of the fixture, and then calculating appropriate offsets for the backside marker. Alternatively, x-ray or infrared methods might be used to compare the locations of the markers on the opposing sides. Once appropriate offsets from the backside markers are determined for printing, those patterns may be used to proceed under conventional methods with mask alignment.

FIG. 7 illustrates the device of FIG. 6 after patterning a resist layer 710, and using the patterned resist layer 710 to form a third opening 720 and fourth opening 730 in an opposing side of the substrate 110. The patterned resist layer 710 and third and fourth openings 720, 730, may be formed using similar process as described above with respect to FIG. 2.

The third and fourth openings 720, 730, may be formed to many different depths. In one embodiment, the third and fourth openings 720, 730 do not extent entirely to the first and second openings 220, 230. In this embodiment, a thin layer of substrate 110 remains between the first and second openings 220, 230 and the third and fourth openings 720, 730, respectively. To accommodate this remaining thin layer of substrate material, the anisotropic etch may be stopped prior to breaking through the entire substrate 110.

The appropriate width (w₂) of the openings in the patterned photoresist layer 710 is a function of the substrate 110 thickness (e.g., wafer substrate 115 and epitaxial layer 120 thickness in one embodiment), desired depth of the openings 720, 730, and the particular etchant used. For instance, in those example embodiments wherein the first and second openings 220, 230 have a shallower depth than the third and fourth opposing openings 720, 730, the width (w₂) should be greater than the width (w₁).

FIG. 8 illustrates the device 100 of FIG. 7 after forming a second insulative layer 810 along sidewalls of the opening 720. The second insulative layer 810, in this embodiment, also extends along the opposing surface of the substrate 110 and along sidewalls of the opening 730. Those skilled in the art understand the materials that may be used for the second insulative layer 810, as well as the processes that might be used for its manufacture. In one embodiment, however, similar materials and processes as those discussed in FIG. 2 could be used.

After depositing the second insulative layer 810 over the opposing surface of the substrate 110, vias may be formed in the second insulative layer 310 at a base of the third and fourth openings 720, 730. The vias are configured to extend through the second insulative layer 310, the thin layer of remaining substrate, and the first insulative layer 310 to expose the first conductive layer 410. Those skilled in the art understand the processes that might be used to form these vias, including any suitable patterning and etching process.

FIG. 9 illustrates the device 100 of FIG. 8 after forming a second conductive layer 910 along at least a portion of the opposing surface of the substrate 110 and lining sidewalls of the third and fourth openings 720, 730. In this embodiment, the second conductive layer 910 extends into the previously formed vias, and thus electrical contacts the first conductive layer 410. Accordingly, an electrical connection is provided between at least a portion of the active semiconductor circuitry 130 and the opposing surface of the substrate 110. If a conductive feature were to be located proximate the opposing surface of the substrate 110, the at least a portion of the active semiconductor circuitry 130 might be in electrical contact with this conductive feature. The second conductive layer 910 may comprise similar materials and be formed using similar processes as described above with respect to FIG. 4.

FIG. 10 illustrates the device 100 of FIG. 9 after forming a bottomside passivation layer 1010 over the second conductive layer 910. The bottomside passivation layer 1010, in the example embodiment of FIG. 10, insulates all but a region configured as a bottomside contact pad 1020. The bottomside passivation layer 1010 may comprise similar materials and be formed using similar processes as described above with respect to FIG. 5.

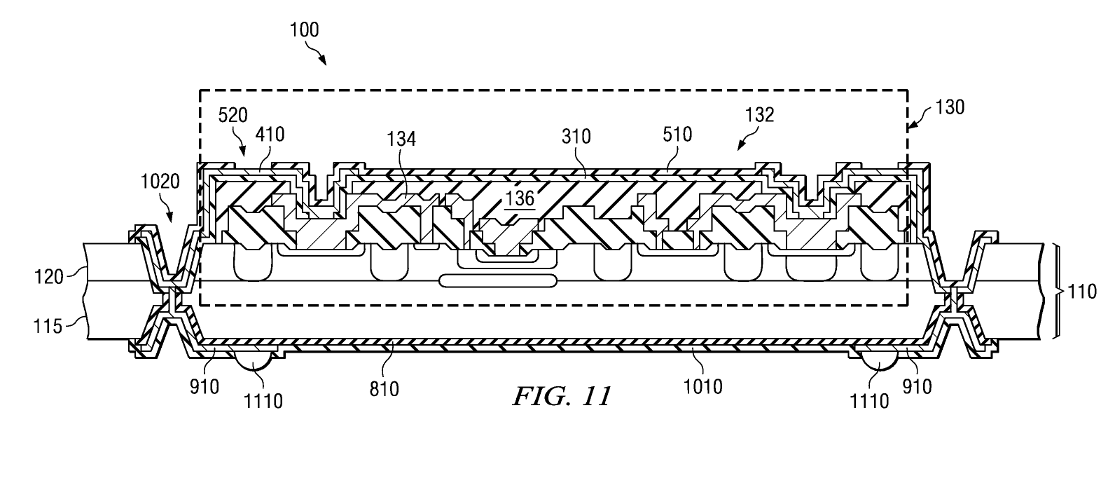

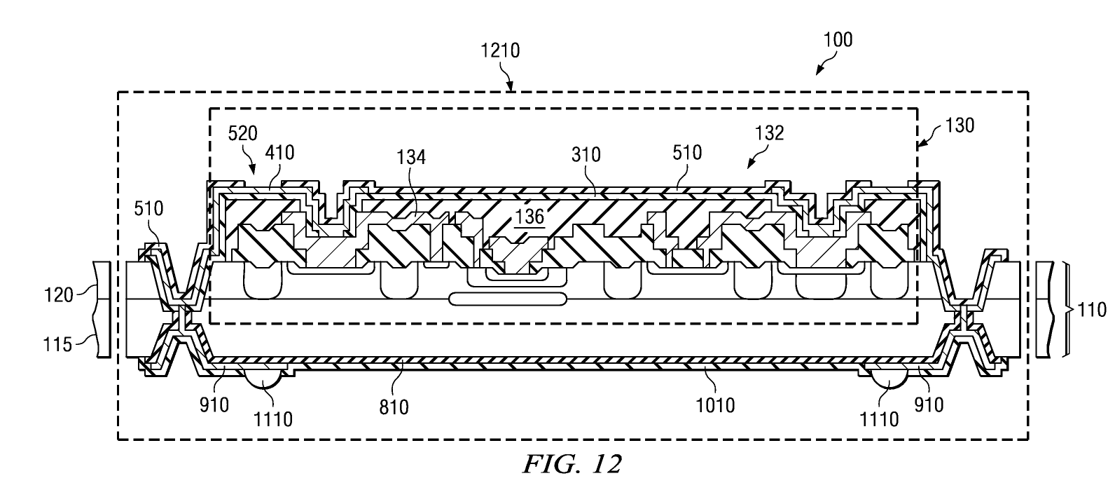

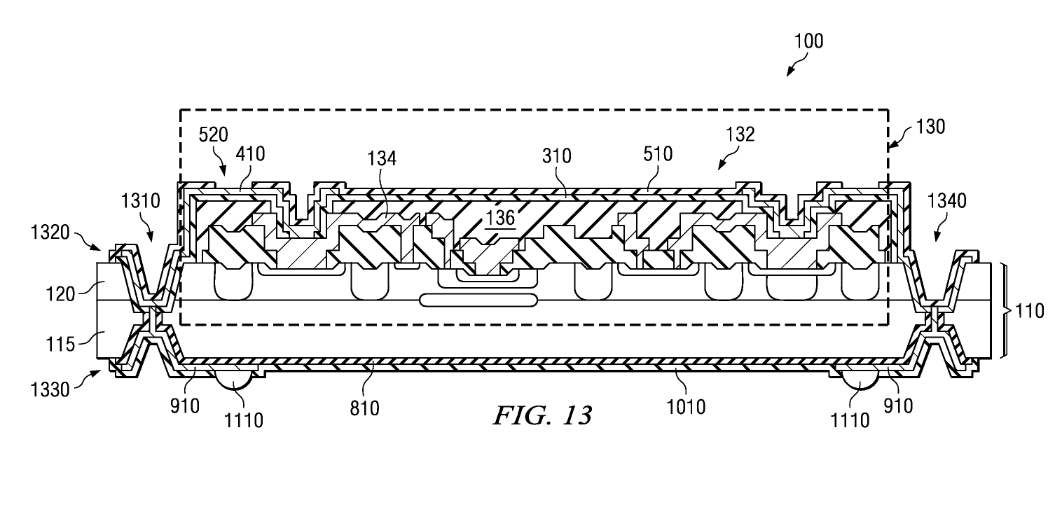

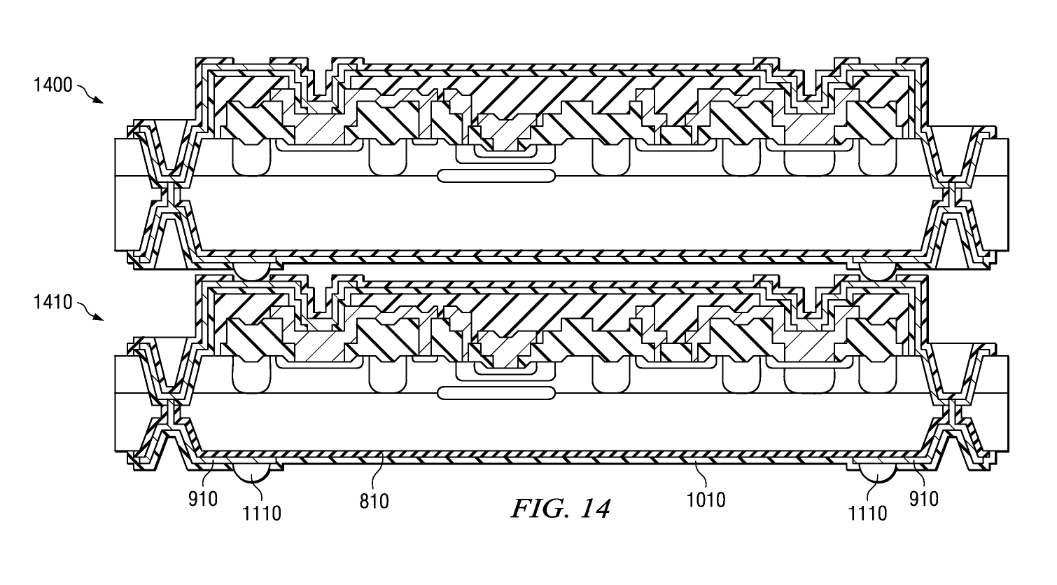

FIG. 11 illustrates the device 100 of FIG. 10 after forming electrical connection points 1110 in contact with the bottomside contact pads 1020. The electrical connection points 1110, in the example embodiment of FIG. 11, are metal balls formed to provide connections to external semiconductor features. If the application requires it, suitable metal pad areas may be provided to allow the forming or attachment of aluminum bumps, coated copper balls, or other methods now used in inverted chip interconnections or BGA arrays. If the electrical connection points 1110 are strategically placed directly below the topside contact pad 520, stacked configurations may be made with multiple dies (FIG. 14). Such ball and bond pad combinations may also accept wire bonding while ball mounted on a printed circuit board, which is useful in the construction of sub-assemblies. Those skilled in the art understand the materials and processes required to form the electrical connection points 1110.

FIG. 12 illustrates the device 100 of FIG. 11 after dicing the substrate 110 into individual semiconductor dies 1210, also referred to as semiconductor dies. In one embodiment a conventional wafer saw method is used to cut the substrate 110 along the scribe line areas 140. Nonetheless, other suitable dicing processes could be used to form the individual semiconductor dies 1210.

FIG. 13 illustrates a completed device 100. The device 100 of FIG. 13 includes the substrate 110 having the active semiconductor circuitry 130 located above a surface thereof. The device 100 further includes a first interconnect 1310 coupling at least a portion of the active semiconductor circuitry 130 and the opposing surface of the substrate 110. The interconnect 1310, in the example embodiment of FIG. 13, includes a first portion 1320 extending from the surface. The first portion 1320 includes the first opening 220 having the first conductive layer 410 in electrical contact with at least a portion of the active semiconductor circuitry 130 and lining sidewalls of the first opening 220. Additionally, a first insulative layer 310 is located between the substrate 110 and the first conductive layer 410 in the first opening 220.

The interconnect 1310 further includes a second portion 1330 extending from the opposing surface. The second portion 1330 includes the third opening 720 having the second conductive layer 910 along at least a portion of the opposing surface and lining sidewalls of the third opening 720. Additionally, a second insulative layer 810 is located between the substrate 110 and the second conductive layer 910 in the third opening 720.

In the embodiment of FIG. 13, the first conductive layer 410 and the second conductive layer 910 electrically contact one another. Accordingly, these layers 410, 910 are configured to provide an electrical connection between the active semiconductor circuitry 130 and a conductive feature located proximate the opposing surface. The interconnect 1310 further has an hour glass cross-section. This hour glass cross-section is at least partially a result of the process used for its manufacture.

The device 100 of FIG. 13 further includes a second interconnect 1340. The second interconnect 1340 is substantially similar to the first interconnect 1310 but for the missing first insulative layer 310 in the second opening 230. As indicated above, the missing first insulative layer 310 allows the second interconnect 1340 to be a ground contact.

FIG. 14 illustrates an alternative embodiment of the disclosure. FIG. 14 indicates that devices of differing, or similar, designs may be interconnected in a stacked configurations, for example so long as the topside contact pad and bottomside contact pad are placed in alignment. In the embodiment of FIG. 14 a device 1400, for example similar to the device 100 of FIG. 13, is stacked upon a related device 1410.

The phrase “providing a substrate having active semiconductor circuitry”, as used herein, means that the substrate having the active semiconductor circuitry may be obtained from a party having already manufactured it, or alternatively may mean manufacturing the substrates or active semiconductor circuitry themselves and providing it for its intended purpose.

Those skilled in the art to which the disclosure relates will appreciate that other and further additions, deletions, substitutions and modifications may be made to the described embodiments without departing from the scope of the disclosure.

What is claimed is:

1. A method for manufacturing a semiconductor device, comprising:
providing a substrate having active semiconductor circuitry located above a surface thereof;
subjecting the surface of the substrate to a first anisotropic etch, the first anisotropic etch forming an opening that extends only partially into the substrate;
subjecting an opposing surface of the substrate to a second anisotropic etch, the second anisotropic etch forming an opposing opening that extends only partially into the substrate;
forming a first conductive layer in electrical contact with at least a portion of the active semiconductor circuitry and lining sidewalls of the opening; and
forming a second conductive layer along at least a portion of the second opposing surface and lining sidewalls of the opposing opening, wherein the first conductive layer and the second conductive layer electrically contact one another and are configured to provide an electrical connection between the at least a portion of the active semiconductor circuitry and a conductive feature located proximate the second opposing surface.

2. The method of claim 1 wherein the subjecting the surface occurs before the subjecting the second surface.

3. The method of claim 2 further including grinding the opposing surface to remove at least a portion thereof prior to subjecting the second surface.

4. The method of claim 1 wherein the active semiconductor circuitry has a passivation layer located thereover exposing one or more bond pads, and further wherein the first conductive layer is in electrical contact with the one or more exposed bond pads.

5. The method of claim 1 further including forming a first insulative layer along sidewalls of the opening prior to forming the first conductive layer lining the sidewalls of the opening.

6. The method of claim 5 further including forming a topside passivation layer over the first conductive layer.

7. The method of claim 6 wherein the topside passivation layer insulates all but a region configured as a topside contact pad.

8. The method of claim 1 further including forming a second insulative layer along sidewalls of the opposing opening prior to forming the second conductive layer lining the sidewalls of the opposing opening.

9. The method of claim 8 further including forming a bottomside passivation layer over the second conductive layer, wherein the bottomside passivation layer insulates all but a region configured as a bottomside contact pad, and further wherein the conductive feature located proximate the second opposing surface is configured to electrically contact the bottomside contact pad.

10. The method of claim 1 wherein the opening is a first opening and the opposing opening is a first opposing opening, and further wherein the subjecting the surface of the substrate to a first anisotropic etch forms a second opening that extends only partially into the substrate and the subjecting the opposing surface to the second anisotropic etch forms a second opposing opening that extends only partially into the substrate, and further wherein the second opening and the second opposing opening open to one another.

11. The method of claim 10 wherein the forming the first conductive layer in electrical contact with at least a portion of the active semiconductor circuitry and lining sidewalls of the first opening includes forming the first conductive layer in direct electrical contact with sidewalls of the second opening to form a ground contact.

12. The method of claim 1 wherein the substrate comprises a wafer substrate, and further including dicing the wafer substrate into one or more individual semiconductor dies after forming the first conductive layer and second conductive layer.

13. The method of claim 1 wherein the opening or opposing opening have a square cross-section or a rectangular cross-section.

14. The method of claim 1 wherein forming the first conductive layer or second conductive layer includes forming by electroplating or sputtering.

15. The method of claim 1 wherein a depth of the opening is less than an opposing depth of the opposing opening.

16. The method of claim 1 wherein the semiconductor device is a first semiconductor device, and further including stacking a second semiconductor device having an additional opening and an additional opposing opening over the first semiconductor device.

17. A semiconductor device, comprising:
a substrate having active semiconductor circuitry located above a surface thereof; and
an interconnect electrically coupling at least a portion of the active semiconductor circuitry and an opposing surface of the substrate, wherein the interconnect includes:
a first portion extending from the surface, the first portion including an opening having a first conductive layer in electrical contact with at least a portion of the active semiconductor circuitry and lining sidewalls of the opening; and
a second portion extending from the opposing surface, the second portion having a second conductive layer along at least a portion of the second opposing surface and lining sidewalls of the opposing opening, wherein the first conductive layer and the second conductive layer electrically contact one another and are configured to provide an electrical connection between the at least a portion of the active semiconductor circuitry and a conductive feature located proximate the second opposing surface, and further wherein the interconnect has an hour glass cross-section.

18. The semiconductor device of claim 17 wherein the active semiconductor circuitry has a passivation layer located thereover exposing one or more bond pads, and further wherein the first conductive layer is in electrical contact with the one or more exposed bond pads.

19. The semiconductor device of claim 17 further including a first insulative layer located along sidewalls of the opening between the substrate and the first conductive layer, and a second insulative layer located along sidewalls of the opposing opening between the substrate and the second conductive layer.

20. The semiconductor device of claim 17 wherein the semiconductor device including the interconnect is a first semiconductor device including a first interconnect, and further including a second semiconductor device having a second interconnect comprising an additional first portion and additional second portion stacked over the first semiconductor device.
